(19) United States
(12) Patent Application Publication
(10) Pub. No.: US 2008/0117615 A1
(43) Pub. Date: May 22, 2008

(54) Plasma display device

(76) Inventor: Woo-Man Jeong, Suwon-si (KR)

Correspondence Address: Robert E. Bushnell, Suite 300, 1522 K Street, N.W., Washington, DC, 20005, US

(21) Appl. No.: 11/711,011

(22) Filed: Feb. 27, 2007

(30) Foreign Application Priority Data
Nov. 21, 2006 (KR) 10-2006-0115147

(51) Int. Cl. H05K 7/02

(52) U.S. Cl. 361/807

(57) ABSTRACT

A Plasma Display Device having a chassis base which absorbs vibration and noise includes: a Plasma Display Panel (PDP) on which images are displayed; circuit board assemblies to control the PDP; and a chassis base having the PDP and the circuit board assemblies attached thereto, the chassis base including: a first plate facing the PDP, a second plate having the circuit board assemblies attached thereto; and at least one vibration absorption member interposed between the first and second plates to absorb vibration and noise.

### CLAIM OF PRIORITY

This application makes reference to, incorporates the same herein, and claims all benefits accruing under 35 U.S.C.§119 from an application for PLASMA DISPLAY DEVICE earlier filed in the Korean Intellectual Property Office on 21 Nov. 2006 and there duly assigned Serial No. 10-2006-0115147.

### BACKGROUND OF THE INVENTION

1. Field of the Invention

The present invention relates to a plasma display device. More particularly, the present invention relates to a plasma display device in which at least one vibration absorption member is included in a chassis base interposed between circuit board assemblies and a panel.

2. Description of the Related Art

A plasma display device displays images on a Plasma Display Panel (PDP) by using a plasma generated through a gas discharge.

The plasma display device includes the PDP and a chassis base that is disposed on a rear surface of the PDP. Circuit board assemblies are disposed on the rear surface of the chassis base. The circuit board assemblies are connected to display electrodes (sustain and scan electrodes) or address electrodes in the PDP through Flexible Printed Circuits (FPCs) or connectors.

The chassis base has functions of supporting the PDP, providing a space in which the circuit board assemblies are disposed, absorbing heat generated in the PDP, and grounding the circuit board assemblies.

The circuit board assemblies are provided with various circuit elements so as to display images on the PDP.

When the gas discharge is carried out, the PDP causes vibration due to an increase of electrostatic force and collides against barrier ribs due to the vibration to generate high frequency noise. Most of the high frequency noise is reduced by the chassis base. However, there is a problem that the rest of the noise is propagated as noise in a specific band.

### SUMMARY OF THE INVENTION

According to an aspect of the present invention, a plasma display device is provided including: a Plasma Display Panel (PDP); circuit board assemblies to control the PDP; and a chassis base having the PDP and the circuit board assemblies attached thereto, the chassis base including: a first plate facing the PDP; a second plate having the circuit board assemblies attached thereto; and at least one vibration absorption member interposed between the first plate and the second plate.

The at least one vibration absorption member preferably includes a material selected from a group consisting of: resins, rubber, plastic, sponges, Styrofoam, and glass fibers.

The plasma display device preferably further includes a plurality of vibration absorption members spaced apart from one another.

The first plate preferably includes either stainless steel or aluminum. The second plate preferably includes either stainless steel or aluminum.

The plasma display device preferably further includes connecting members to electrically connect the first plate to the second plate.

A reinforcing material is preferably arranged on a surface of the second plate.

The first plates, the second plates and the at least one vibration absorption member each preferably include apertures; and the at least one vibration absorption member is preferably attached to the first plates and the second plates by set screws passing through the apertures.

### BRIEF DESCRIPTION OF THE DRAWINGS

A more complete appreciation of the present invention and many of the attendant advantages thereof, will be readily apparent as the present invention becomes better understood by reference to the following detailed description when considered in conjunction with the accompanying drawings in which like reference symbols indicate the same or similar components, wherein:

FIG. 1 is a perspective view of a plasma display device according to a first embodiment of the present invention;

FIG. 2 is a cross-sectional view taken along line II-II of FIG. 1;

FIG. 3 is a partially exploded perspective view of FIG. 1;

FIG. 4 is a detailed cross-sectional view of a portion of a chassis base; and

FIG. 5 is a top plan view of an inside of a chassis base according to a second embodiment of the present invention.

### DETAILED DESCRIPTION OF THE INVENTION

The present invention is described more fully hereinafter with reference to the accompanying drawings, in which exemplary embodiments of the present invention are shown.

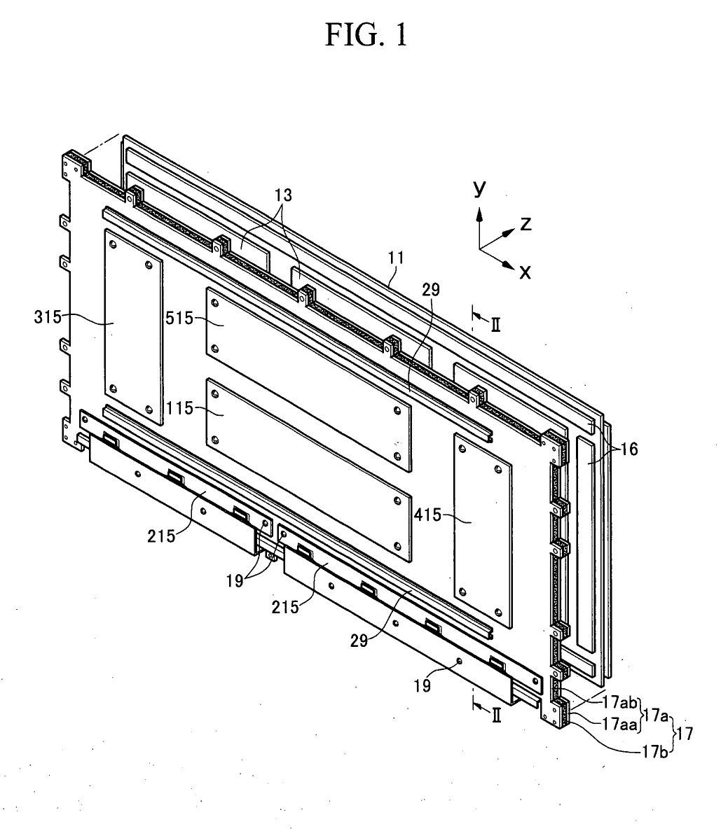

FIG. 1 is a perspective view of a plasma display device according to a first embodiment of the present invention.

Referring to FIG. 1, the plasma display device according to the first embodiment of the present invention includes a PDP 11 which displays images by using a gas discharge, heat dissipating sheets 13 which are disposed on a rear surface of the PDP 11 so as to radiate heat generated by the PDP 11, circuit board assemblies 115, 215, 315, 415, and 515 which are electrically connected to the PDP 11 to drive the PDP 11, and a chassis base 17 having a front surface including double-sided tapes 16 attached thereto to support the PDP 11 and a rear surface having the circuit board assemblies 115, 215, 315, 415, and 515 attached thereto.

The embodiment of the present invention relates to a connection structure between the PDP 11 and other components. Therefore, a detailed description of the internal structure of the PDP 11 has been omitted.

The heat dissipating sheets 13 are disposed between the PDP 11 and the chassis base 17 to radiate heat generated during a gas discharge process away from the PDP 11. Accordingly, the heat dissipating sheets 13 are made of a material having a high thermal conductivity, for example, an acrylic heat dissipating material, a graphite heat dissipating material, a metallic heat dissipating material, or a carbon nano-tube heat dissipating material.

The circuit board assemblies 115, 215, 315, 415, and 515 are attached to the chassis base 17 using set screws 19. The circuit board assemblies 115, 215, 315, 415, and 515 include an image process/control board 115, an address buffer board 215, a scan driving board 315, a sustain driving board 415, and a power source board 515.

The image process/control board 115 generates a control signal for driving address electrodes (not shown) and a control signal for driving display electrodes (not shown). In addition, the image process/control board 115 supplies the control signals to the address buffer board 215, the scan driving board 315, and the sustain driving board 415. The power source board 515 is used to supply power for driving the plasma display device.

The address buffer board 215, the scan driving board 315, and the sustain driving board 415 are connected to corresponding electrodes to drive the PDP 11.

The chassis base 17 may be formed by performing a press fabrication operation with respect to a thin metal plate. In addition, a reinforcing member 29 may be disposed on the rear surface of the chassis base 17 so as to prevent distortion or bending of the chassis base 17.

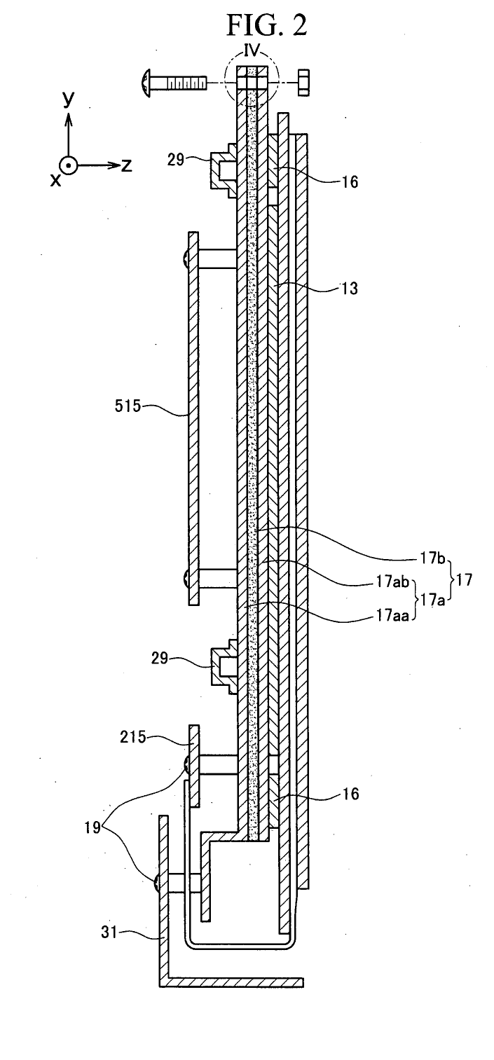

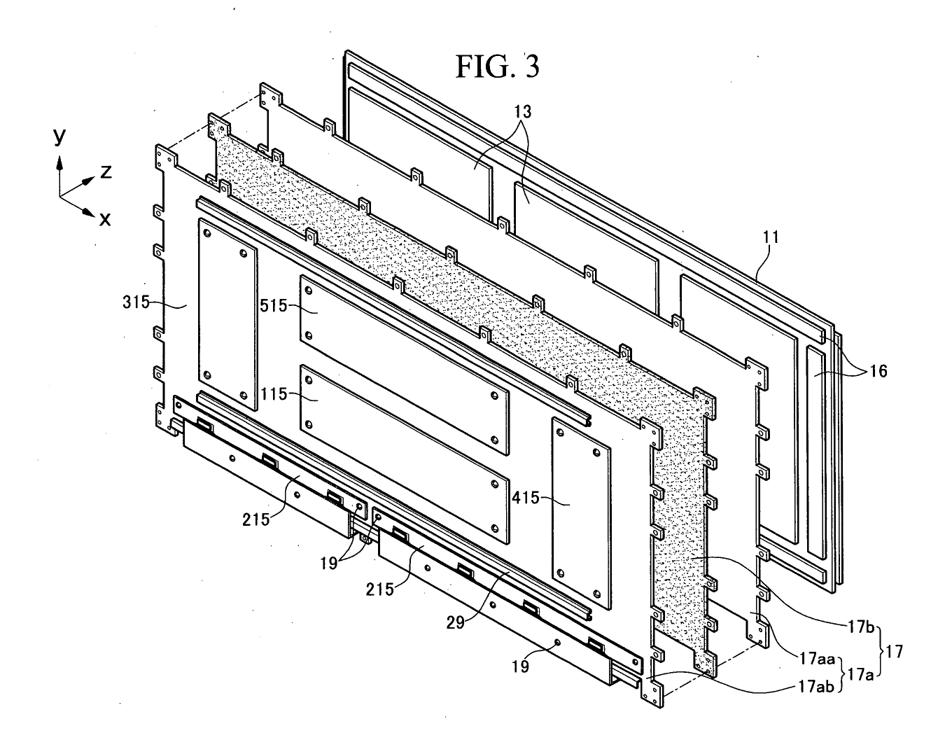

FIG. 2 is a cross-sectional view taken along line II-II of FIG. 1. FIG. 3 is a partially exploded perspective view of FIG. 1.

Referring to FIGS. 2 and 3, the chassis base 17 includes a plate member 17a and a vibration absorption member 17b.

The plate member 17a includes first and second plates 17aa and 17ab. The first plate 17aa has a substantially rectangular shape. The second plate 17ab, which has a rectangular shape, faces the first plate 17aa and is spaced apart from the first plate 17aa. However, the shape of the first or second plate 17aa or 17ab is not limited to the rectangular shape. The first and second plates 17aa and 17ab may have various shapes. The first and second plates 17aa and 17ab may be made of metal, such as stainless steel or aluminum.

The vibration absorption member 17b is interposed between the first and second plates 17aa and 17ab and closely attached to the first and second plates 17aa and 17ab. Noise is prevented from occurring by absorbing vibration generated during the gas discharge process.

As described above, when the vibration absorption member 17b is not included, the chassis base 17 contacts the surface of the display panel 11 due to the vibration transmitted from the PDP 11 to the chassis base 17, and accordingly noise is generated.

However, according to the embodiment of the present invention, the vibration absorption member 17b, which is closely attached to the chassis base 17, absorbs the vibration transmitted from the PDP 11 to the first plate 17aa of the chassis base 17. Accordingly, the chassis base 17 is prevented from contacting the PDP 11, and noise is prevented from occurring.

On the other hand, the vibration absorption member 17b may be made of various materials, such as resins, plastic, sponges, Styrofoam, and glass fibers.

Vibration may also be generated in the circuit board assemblies 215 and 515. According to the embodiment of the present invention, although the generated vibration is transmitted to the chassis base 17, the vibration is absorbed by the vibration absorption member 17b, and therefore, the noise is prevented from occurring.

Since the chassis base 17 has a function of absorbing electromagnetic waves (for example, ElectroMagnetic Interference (EMI), etc), the first and second plates 17aa and 17ab are electrically connected to each other by connection members (not shown).

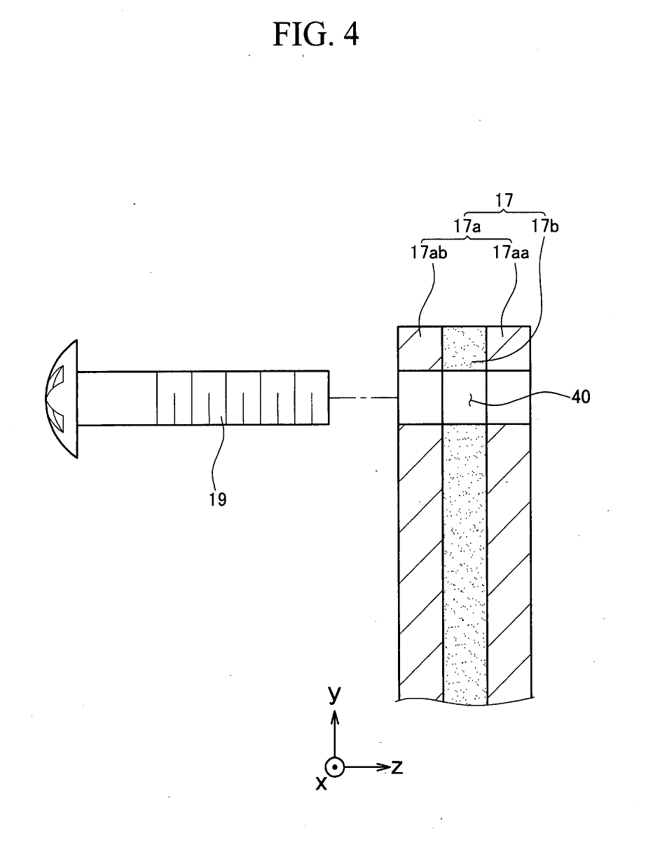

FIG. 4 is a detailed cross-sectional view of a portion of a chassis base 17.

Referring to FIG. 4, the first and second plates 17aa and 17ab and the vibration absorption member 17b are provided with holes 40 and connected to one another by the set screws 19 to be engaged with the holes 40.

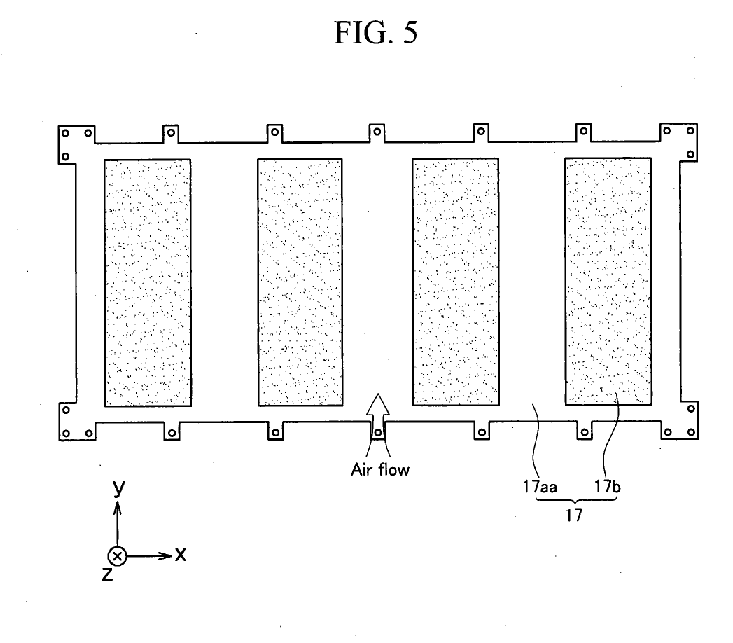

FIG. 5 is a top plan view of an inside of a chassis base 17 according to a second embodiment of the present invention.

Referring to FIG. 5, the vibration absorption member 17b is attached to the first plate 17aa. There may be a plurality of the vibration absorption members 17b which are spaced apart from one another. Spaces may be formed between neighboring vibration absorption members 17b. Air flowing through the spaces has a function of radiating heat by extracting heat from the chassis base 17.

While this invention has been described in connection with what is presently considered to be practical exemplary embodiments, it is to be understood that the present invention is not limited to the embodiments discussed above, but, on the contrary, is intended to cover various modifications and equivalent arrangements included within the spirit and scope of the appended claims.

What is claimed is:

1. A plasma display device comprising:
a Plasma Display Panel (PDP);
circuit board assemblies to control the PDP; and
a chassis base having the PDP and the circuit board assemblies attached thereto, the chassis base including:
a first plate facing the PDP;
a second plate having the circuit board assemblies attached thereto; and
at least one vibration absorption member interposed between the first plate and the second plate.

2. The plasma display device of claim 1, wherein the at least one vibration absorption member comprises a material selected from a group consisting of: resins, rubber, plastic, sponges, Styrofoam, and glass fibers.

3. The plasma display device of claim 1, further comprising a plurality of vibration absorption members spaced apart from one another.

4. The plasma display device of claim 1, wherein the first plate comprises either stainless steel or aluminum.

5. The plasma display device of claim 4, wherein the second plate comprises either stainless steel or aluminum.

6. The plasma display device of claim 1, further comprising connecting members to electrically connect the first plate to the second plate.

7. The plasma display device of claim 1, wherein a reinforcing material is arranged on a surface of the second plate.

8. The plasma display device of claim 1,
wherein the first plates, the second plates and the at least one vibration absorption member each include apertures; and
wherein the at least one vibration absorption member is attached to the first plates and the second plates by set screws passing through the apertures.
